(19) United States
(12) Patent Application Publication
(10) Pub. No.: US 2014/0055011 A1
(43) Pub. Date: Feb. 27, 2014

(54) Housing for Holding a Flat Screen

(71) Applicant: Ruf Telematik AG, Schlieren (CH)

(72) Inventors: Stefan Brunner, Niederlenz (CH); Fred Engler, Dietikon (CH); Thomas Kern, Wetzikon (CH)

(73) Assignee: Ruf Telematik AG, Schlieren (CH)

(21) Appl. No.: 13/973,201

(22) Filed: Aug. 22, 2013

(30) Foreign Application Priority Data
Aug. 22, 2012 (EP) 12 181 373.7

(51) Int. Cl. H05K 7/20; H05K 7/18

(52) U.S. Cl. CPC H05K 7/2039; H05K 7/18
USPC 312/7.2; 29/428; 72/379.2

(57) ABSTRACT

A housing is provided for holding a flat screen, having a frame which defines a housing interior for holding the flat screen. The frame is produced from a flat profile element which has multiple set bending points which serve to establish the corner regions of the frame. On its inside, the frame has an inner channel into which a heat-dissipating element is inserted in such a way that it serves to transmit heat from the housing interior to the frame.

### CROSS-REFERENCE TO RELATED APPLICATIONS

This application claims priority to European Patent Application No. 12 181 373.7, filed Aug. 22, 2012 in the European Intellectual Property Office, the disclosure of which is hereby incorporated by reference in its entirety.

### BACKGROUND OF THE INVENTION

The present invention relates to a housing for holding a flat screen, to a method for producing a housing of this type, and to a device that has such a housing and a flat screen held therein. Housings of this type are usually used when installing flat screens in public places, and in particular in vehicles, as an installation and protective device for the flat screen.

### PRIOR ART

Flat screens are often mounted in public places, and in particular in public transport vehicles, in order to let a corresponding public have access to information or in order to entertain them. LCD, TFT, FED or LED screens can be used to do this, as also can plasma screens or other types of flat screens. Today it is usually common to provide multiple flat screens in a vehicle, in particular in buses, trains and aeroplanes, in order to display, for example, current timetables, safety precautions or world news to the passengers. The flat screens are usually held in a housing in order to fasten them and protect them from external mechanical damage. The housing with the flat screen held therein is then fastened at an appropriate point, which can be easily seen by the corresponding audience, on or in a building or a vehicle, etc.

A housing of the type described at the beginning is described, for example, in U.S. Pat. No. 7,619,881.

Because it is intended that housings of this type provide protection in particular against external and especially mechanical influences, they should have a robust form of construction and be designed in such a way that the flat screens held therein are protected if possible on all sides. In the prior art, housings are often used which are produced from cast aluminium or machined aluminium. However, they have the disadvantages of considerable weight and the complex and expensive production of cast or machined housings of this type.

Because electronic appliances generally and flat screens specifically produce heat while they are working, mainly owing to their backlighting, the heat dissipation to the outside represents a further important requirement for housings of this type for holding a flat screen. The documents U.S. Pat. No. 7,876,553, US 2012/0075802 and U.S. Pat. No. 7,259,964 disclose housings for flat screens, which in each case make special provision for dissipating the heat resulting from the backlighting of the flat screen. As a rule, rib structures attached to the housing are used hereby, which serve to dissipate the heat to the outside.

However, in many cases, in spite of all the provisions made, the heat dissipation is insufficient and a build-up of heat results inside the housing.

Most housings from the prior art have a relatively complex and correspondingly expensive form of construction. For the most part, the housings are designed for specific types and sizes of flat screens, and the production process for these housings can be adapted to differently designed flat screens only with a relatively great degree of complexity. Moreover, in the case of housings from the prior art, direct contact of the heat-dissipating structures with the flat screen is not always ensured owing to manufacturing tolerances. The problem follows that the heat generated in the flat screen in particular in the region of the backlighting cannot be dissipated to the outside sufficiently well. In extreme cases, this can result in irreversible damage to the flat screen.

### DESCRIPTION OF THE INVENTION

An object of the present invention is therefore to provide a housing for holding a flat screen, which can not only be produced relatively simply and inexpensively but can also be adapted simply, to flat screens of all types and sizes.

A further object of the present invention is providing a housing for holding a flat screen, where dissipation of the heat generated in the flat screen to the outside is ensured at all times in a sufficient quantity.

In addition, a device is provided which has a housing and a flat screen held therein.

The present invention thus makes available a housing for holding a flat screen having a frame that defines a housing interior for holding the flat screen. The frame is produced from a flat profile element that is in particular extruded and has multiple set bending points that serve to establish the corner regions of the frame.

As a rule, the frame of the housing surrounds the sides of the housing interior, in other words facing that side of the flat screen held in the housing which extends perpendicularly to the display surface of the screen. Because the frame is produced from a flat profile element with correspondingly provided set bending points, the frame and thus the housing can be produced extremely simply and inexpensively and in particular can be adapted during production to all types and sizes of flat screens. The flat profile element, which as a rule is a single piece, is preferably made from a metal and in particular preferably from aluminium. Consequently the weight of the housing is approximately 40% less than a corresponding housing made from cast aluminium. Moreover, the thermal conductivity of aluminium profiles and especially extruded aluminium profiles is significantly better than those made from cast aluminium.

The flat screen can in particular be an LCD, TFT, FED or LED screen, or also a plasma screen. Depending on the design, the flat screen can in particular also be referred to as a display panel, a display or a monitor. In principle, the flat screen has a relatively much lower thickness in comparison to its other dimensions, measured in a direction perpendicular to the display surface.

A flat profile element is usually chosen which has a width that is more or less the same or slightly larger than the thickness of the flat screen that needs to be held in the housing. The thickness of the flat screen hereby and hereunder means the dimension which extends perpendicularly to the display surface of the screen.

When producing the frame, as a rule in a first step the length of the flat profile element is adapted to the peripheral length of the flat screen so that later a frame preferably results which is designed in such a way that it surrounds the sides of the flat screen to a large extent and in particular preferably essentially completely. The length of the flat profile element thus preferably corresponds more or less to the peripheral length of the flat screen. In a second step, as a rule multiple, in particular precisely three or precisely four, set bending points are then provided lengthwise on the flat profile element in order to establish the positions of the corner regions of the subsequent frame. The distances between the different set bending points lengthwise on the flat profile element advantageously here correspond more or less to the lengths of the sides of the flat screen. In a third step, the flat profile element can then be bent in the regions of the set bending points preferably by in each case more than 80° and less than 100°, in particular approximately 90° so that an advantageously rectangular frame results that is suited for holding the flat screen. Of course, other steps can be carried out when producing the frame. In particular, holes, recesses and grooves can be provided on the flat profile element.

In what follows, positional and directional indications such as up, down, front, back, above, below, inside and outside refer to a housing, mounted for the intended purpose for example on or in a vehicle or on or in a building, with a flat screen held therein, in which the display surface is facing forwards and extends approximately parallel to the force of gravity so that an observer standing upright has the best possible view of the flat screen arranged at eye level.

The set bending points are preferably in each case defined by a thinner region of material at the corresponding positions. The thinner region of material can be produced in any desired fashion, such as in particular using a machining process, i.e. milling for example, and advantageously but not necessarily extends essentially over the entire width of the flat profile element and thus in particular essentially in a direction perpendicular to the longitudinal direction. Where the set bending points are each defined by a thinner region of material, the flat profile element can be bent into a frame particularly simply and accurately, with a relatively small amount of force being exerted. The thinner regions of material are advantageously in each case provided in the form of depressions on that side of the flat profile element that forms the side facing the housing interior when the frame has been completed.

If the set bending points are defined by thinner regions of material, the flat profile element is made thinner at the corresponding positions in each case preferably by at least half, more preferably by at least two-thirds and most preferably by at least three-quarters the material thickness.

The thinner regions of material are preferably each formed by a groove that can have any desired shape. Thus the groove can, for example, in particular have a V-shaped or U-shaped design. However, the groove preferably takes the form of a combination of a V-shaped and a U-shaped groove. A groove with such a combined form is delimited by two flat surfaces and a curved surface arranged between the latter. A groove with such a design forms a clearly defined set bending point that allows the flat profile element to be bent simply and accurately at the corresponding position. The bending then takes place in particular in the region of the curved surface of the groove. The radius of the curved surface is preferably one-twelfth, more preferably one-tenth and most preferably one-eighth of the thickness of the flat profile element.

The two flat surfaces of the groove preferably enclose an angle of more than 60° and less than 120°, in particular more than 80° and less than 100°. Most advantageously, however, they enclose an angle of approximately 90°. In the finished frame, the two flat surfaces of the groove then preferably extend essentially parallel to each other and in particular preferably bear against each other.

The frame preferably forms an essentially closed rectangle, the lengths of the sides of which are advantageously approximately in a ratio of 4:3, 15:9, 16:9 or 16:10 to each other. Thus the frame can in particular have a joining point at which the two ends of the flat profile element are joined together. The frame is thus advantageously designed in such a way that it essentially completely encloses laterally in peripheral direction a flat screen held in the housing. A joining plate, by means of which the two ends of the flat profile element are joined together, can be provided in particular in the region of the joining point. This joining plate is preferably fastened on the outside of the frame. The two end faces of the flat profile element in the longitudinal direction can bear against each other but don't need to. However, they are preferably arranged in the immediate vicinity of each other. The joining point is preferably arranged at a distance from the corner regions of the frame and in particular preferably within one of the long sides of the frame, most preferably within the bottom long side of the frame. However, the joining point is here advantageously arranged in the vicinity of one of the corner regions of the frame. Alternatively, the joining point can, however, in particular also form one of the corner regions of the frame.

The frame preferably has a recess that serves to hold an electronic component and is arranged in particular in the region of the joining point. This recess is preferably surrounded laterally completely by the material of the frame. In a preferred embodiment, the two ends of the flat profile element together define the recess. In such an embodiment, both ends of the flat profile element advantageously each have a recess that is open towards the outside in the longitudinal direction of the flat profile element. The electronic component can in particular be a printed circuit board that can have display elements such as LEDs and sensors which serve, for example, to display the operating mode of the flat screen and to measure the environmental light conditions. In order to ensure that the LEDs or the sensors of the printed circuit board are visible to an observer from the front, the frame can have correspondingly arranged holes which extend from an inner surface defining the recess to a forward-facing upper surface of the frame.

If a recess is present in the frame, notches can additionally be provided on the frame in the region of the recess which serve to retain the printed circuit board in the recess. Correspondingly designed, laterally protruding projections of the printed circuit board, which in particular each have the form of a pin, can then be inserted into the notches in order to retain the printed circuit board in the recess. The notches can here in particular be designed so that they are open towards the recess and preferably also towards that side to which a joining plate on the frame is attached. By attaching the joining plate on the frame, the notches are then preferably closed towards the corresponding side so that a printed circuit board inserted into the notches with its lateral projections is retained in the housing.

The housing usually has a rear wall which serves to close to the rear the housing interior defined laterally by the frame. At least one joining tab, which serves to fasten the rear wall on the frame, is preferably attached to the rear wall. In a preferred embodiment, the one or more joining tabs are advantageously attached to the rear wall essentially along the entire periphery in such a way that they protrude essentially perpendicularly from said rear wall. The rear wall is preferably produced, together with the joining tabs attached thereto, in a single piece from a metal sheet, in particular an aluminium sheet. The joining tabs can be joined to the frame in particular by means of screws which, before they are tightened up, advantageously have a certain amount of play in corresponding joining holes of the frame provided for them. The housing can then be simply disassembled and put back together again, for example to carry out repairs, and it can be ensured that the rear wall bears at all times against the rear of the flat screen held in the housing.

The present invention moreover makes available a housing which can be designed as described above, serves to hold a flat screen and has a frame which defines a housing interior for holding the flat screen, and at least one heat-dissipating element which is attached to the inside of the frame and serves to transmit heat that is generated in the housing interior to the frame. The frame here has an inner channel, into which the heat-dissipating element is inserted, on its side facing the housing interior.

In the case of such a design for the housing, the flat screen held therein can be clamped in particular between the heat-dissipating element and, for example, a rear wall of the housing. In this way it can be ensured that the flat screen is in contact at all times with the heat-dissipating element, as a result of which it is ensured that the heat generated in the flat screen is dissipated.

It has been shown that it is often misunderstood that the main problem of the heat dissipation is transporting the heat inside from the flat screen to the housing and not from the housing to the surroundings. In these cases, attaching complex ribs to the outside of the housing usually does not result in a significant improvement in the heat dissipation because the surface of the housing is in most cases already large enough to emit the heat to the surroundings even without the presence of ribs. However, with the present invention the heat transfer from the flat screen to the housing is ensured at all times and hence a build-up of heat is prevented.

The heat-dissipating element can be any element which projects from the frame into the housing interior and is preferably made from a metal, in particular aluminium. However, the heat-dissipating element preferably takes the form of a strip that is inserted into the inner channel along one of its long sides. The heat-dissipating element can be fastened in the inner channel by being press-fitted and/or fixed in the inner channel by means of an adhesive or another fastening means such as, for example, screws.

In a preferred embodiment, the inner channel and in particular also the heat-dissipating element extend over the entire periphery of the housing interior defined by the frame. The heat-dissipating element can, however, also extend over only part of the periphery and in particular be provided only along an upper long side of the frame.

In a preferred embodiment, the housing additionally has a front panel which can be bonded to the heat-dissipating element and in particular to its forward-facing sides. The heat-dissipating element is then therefore advantageously arranged between the flat screen and the front panel which as a rule serves to protect the display surface of the flat screen. The housing can moreover have a front trim which can preferably be screwed to the frame and is advantageously designed in such a way that it completely covers the heat-dissipating element at the front, facing the observer.

A housing which is designed according to the above embodiments can as a whole be produced very simply and inexpensively, and the dissipation of the heat generated in the housing can be ensured at all times in a simple fashion.

### SHORT DESCRIPTION OF THE DRAWINGS

Preferred embodiments of the invention are described below with reference to the drawings which are provided purely for the purpose of explanation, imply no limitation, and in which:

FIG. 1 shows a perspective view from the front of a housing according to a preferred embodiment according to the invention, for holding a flat screen;

FIG. 2 shows a perspective view of the housing in FIG. 1 from behind;

FIG. 3 shows a perspective view of the frame of the housing in FIG. 1 from the front;

FIG. 4 shows a perspective partial view of the frame in FIG. 3 from the front;

FIG. 5 shows a front partial view of the frame of the housing in FIG. 1 from behind, with a joining plate attached thereto;

FIG. 6 shows a much enlarged front partial view from behind of the flat profile element which serves to produce the frame of the housing in FIG. 1;

FIG. 7 shows a perspective view from the front of the frame of the housing in FIG. 1, with a joining plate attached thereto;

FIG. 8 shows a perspective partial view of the frame of the housing in FIG. 1 from the inside, with a joining plate attached thereto;

FIG. 9 shows a perspective view of the frame of the housing in FIG. 1 from the front, with heat-dissipating strips attached thereto;

FIG. 10 shows a view in section of the housing in FIG. 1 along the plane X-X designated in FIG. 2;

FIG. 11 shows an enlarged detailed view of the region marked in FIG. 10, and

FIG. 12 shows a view in section of the housing in FIG. 1 along the plane XII-XII designated in FIG. 2.

### DESCRIPTION OF THE PREFERRED EMBODIMENTS

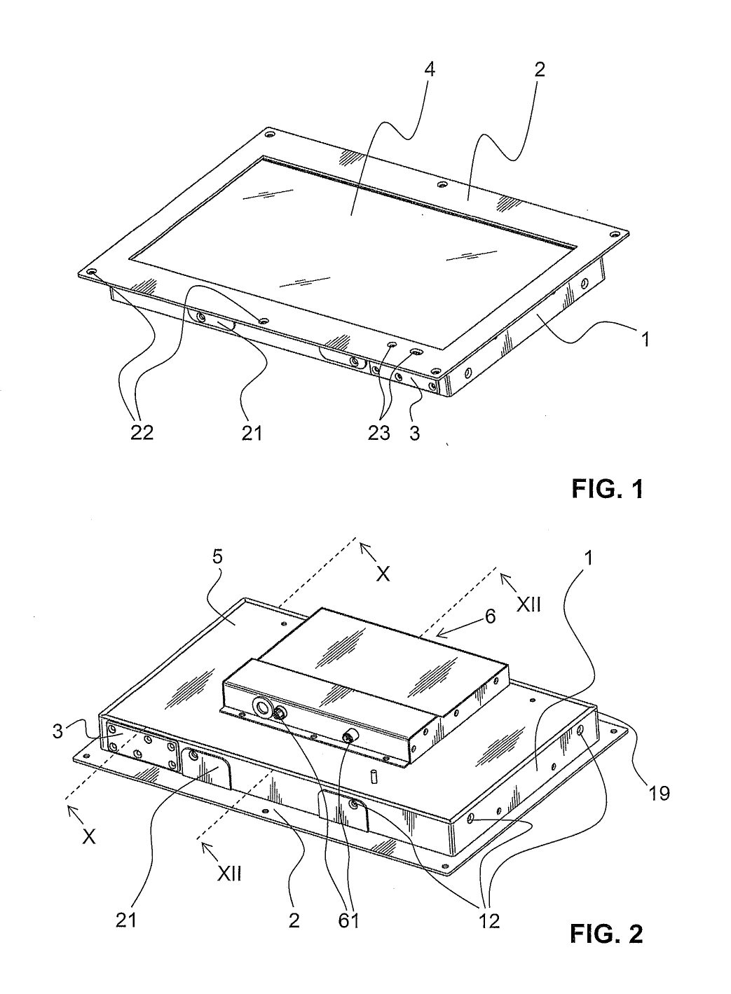

A housing according to a first embodiment according to the invention, for holding a flat screen, is shown in FIGS. 1 and 2. The housing has a housing interior 8 which is suitable for holding a flat screen and which is defined essentially laterally by a frame 1, to the front by a front panel 4 and to the rear by a rear wall 5.

A front trim 2, which has a large rectangular opening through which the display surface or the display of the screen held in the housing can be seen, is attached to the frame 1 in the region of the front side of the housing. Multiple joining tabs 21, which bear against the outside of the frame 1 when the housing is assembled, are attached to the rear side of the front trim 2 for connection to the frame 1. The joining tabs 21 each have holes which correspond with joining holes 12 of the frame 1 in order to allow screw connections between the front trim 2 and the frame 1.

Multiple holes 22, which serve to fasten the front trim 2, for example, on or in a vehicle or building, are provided in a region of the front trim 2 which extends essentially parallel to the front panel 4 and hence to the viewing side of a flat screen held in the housing, and which additionally projects laterally outwards beyond the frame 1.

The front trim 2 additionally has recesses 23 which allow a user to view an LED display arranged behind them. The LED display, the arrangement of which in the housing is explained more precisely below, can, for example, serve to display the operating mode or the presence of a mains voltage at the flat screen. However, sensors which can be used, for example, to measure the environmental light can also be arranged behind the recesses 23.

In the present exemplary embodiment, a control circuit module 6, which has a housing which is separate from the housing for the flat screen and serves, for example, to hold a control circuit for controlling the flat screen, is attached to the outside of the rear wall 5. In the region of their two surfaces which bear against each other, the rear wall 5 and the control circuit module 6 each have at least one corresponding recess which serves for the passage of cable harnesses or control lines. The control circuit module 6 has connectors 61 on its outside in order to supply the control circuit module 6, for example, with mains voltage or connect it to a data communication cable. Because the electronic components for controlling the flat screen are accommodated in a separate housing of the control circuit module 6, the air spaces which are concerned with the development of heat from the flat screen or the electronic control system are essentially completely separated from one another so that the heat generated in each case can be dissipated independently.

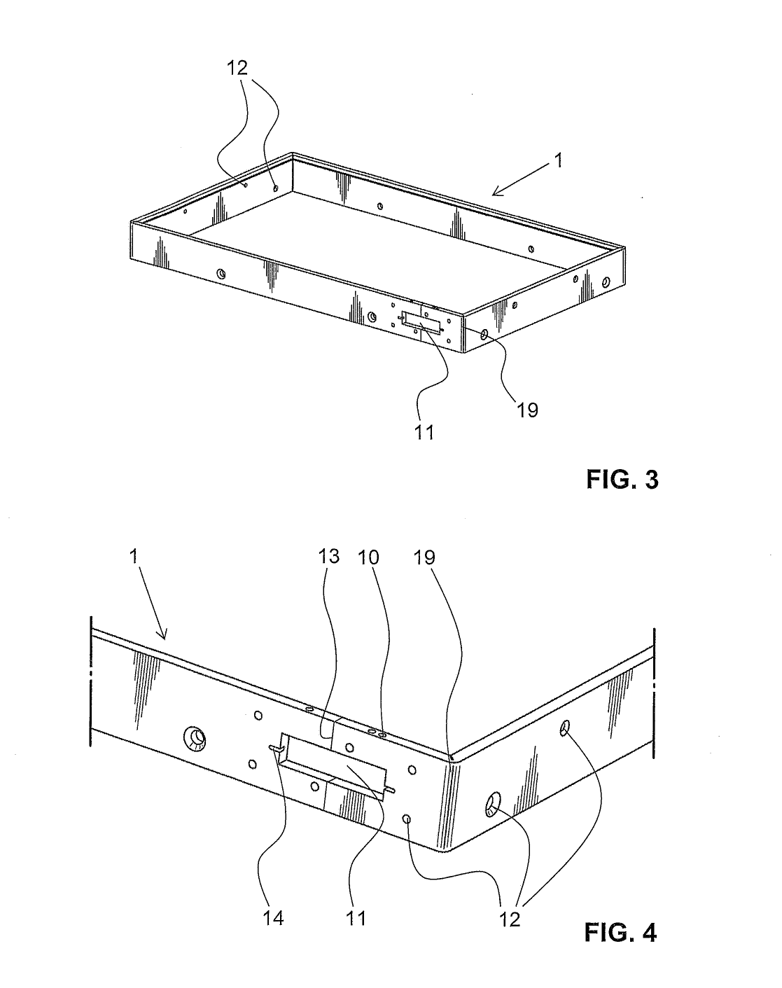

The design of the frame 1 can be clearly seen in particular in FIGS. 3 to 6. The frame 1 is made from a simple flat profile element which in turn can be produced by simple extrusion of a metal such as in particular aluminium. The length of the flat profile element used is here chosen in such a way that it is slightly longer than the lateral periphery of the flat screen to be gripped. Multiple set bending points, which serve to establish the corner regions 19 of the frame 1, are machined in the flat profile element in order to produce the frame 1.

The set bending points are here each designed as grooves 15 which extend essentially perpendicularly to the longitudinal direction of the flat profile element over its entire width. In the present case, precisely four grooves 15 are provided. The depth of the grooves is here in each case approximately two-thirds to approximately three-quarters of the thickness of the flat profile element. The grooves 15 are machined in the flat profile element by means of a spherical cutter in such a way that, as can be seen in FIG. 6, they are defined by two flat surfaces 16 and a curved surface 17 lying in between. The flat surfaces 16 here enclose an angle of approximately 90°.

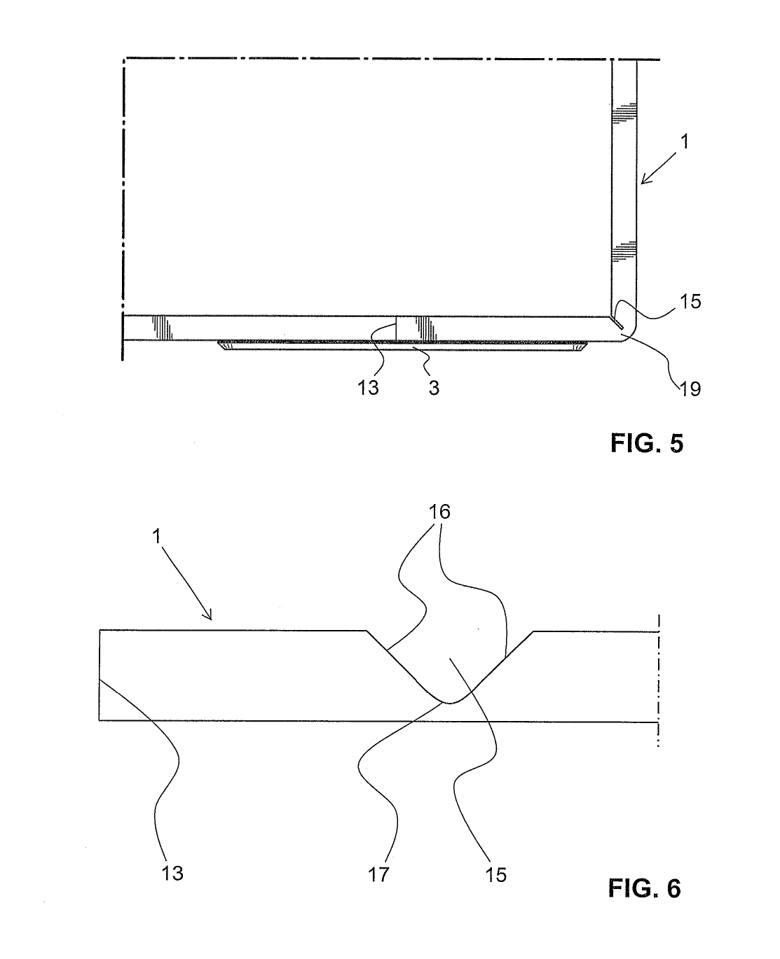

By virtue of providing the grooves 15, the flat profile element can then be brought into the rectangular shape of the frame 1, shown in FIG. 3, with well-defined corner regions 19 by expending a small amount of force and precisely. After the flat profile element has been bent to form the frame 1, the flat surfaces 16 of the grooves 15 each extend parallel to each other and essentially parallel to the bisecting lines predetermined by the respective corner region 19 (see FIG. 5).

Moreover, multiple joining holes 12, which in particular enable screw joints to be made with the front trim 2, the rear wall 5 and the joining plate 3 (explained below), are formed on the frame 1. The joining holes 12 can each be provided with an internal thread. The joints can, however, also be effected by means of bolts and nuts. Alternatively, however, the joints of the said components can also take the form of adhesive or riveted joints.

The flat profile element used to produce the frame 1 has, in the longitudinal direction, two ends which, in the present exemplary embodiment, are arranged directly next to each other or even bear against each other after the frame 1 has been formed in order to form a joining point 13. This joining point 13 is joined by means of a joining plate 3, as shown in FIGS. 5, 7 and 8. This joining plate 3 is screwed on to the outside of the frame 1 in such a way that it is firmly attached to both ends of the flat profile element. In order to screw the joining plate 3 to the frame 1, the joining plate 3 and the frame 1 each have mutually corresponding holes 31 and 12 in the region of the joining point 13.

The frame 1 has a recess 11 in the region of the joining point 13. In the flat profile element provided to produce the frame 1, this recess 11 is designed in the region of both of the ends in each case as a recess that is open to the outside. By virtue of the recess 11, the two ends of the flat profile element therefore each have an essentially U-shaped form. After the two ends of the flat profile element have been joined at the joining point 13, the recess 11 describes a rectangular shape which is completely covered from below by the joining plate 3.

The recess 11 serves to hold an electronic component which can in particular take the form of a printed circuit board. In the present exemplary embodiment, the recess 11 serves to hold a printed circuit board equipped with LEDs and sensors. The LEDs and sensors serve to display the operating mode of the flat screen held in the housing and to measure the environmental light conditions, respectively. To do this, the frame 1 has viewing holes 10 which extend from an inner surface of the recess 11 to the forward-facing surface of the frame 1 and which thus extend essentially parallel to the direction in which an observer usually views the display surface of a screen held in the housing. The viewing holes 10 are each arranged in such a way that they align with the recesses 23 of the front trim 2 when the latter is attached to the frame 1. A line of sight from outside to the LEDs and sensors of the printed circuit board is thus ensured through the viewing holes 10 and the recesses 23, respectively.

In order to retain the electronic component or the printed circuit board with the LEDs and sensors in the recess 11, two opposing notches 14 are present on the edge of the recess 11. The notches 14 are designed to hold correspondingly shaped pins which are attached to the printed circuit board and project laterally from the latter. For this purpose, the notches 14 are in each case designed so that they are open towards the recess 11 and the underside of the frame 1. Consequently, a printed circuit board can be inserted simply from below into the recess 11 and with the laterally projecting pins into the notches 14. When the joining plate 3 is attached to the frame 1, the notches 14 are closed from below so that the printed circuit board is retained in the notches 14 with its laterally projecting pins.

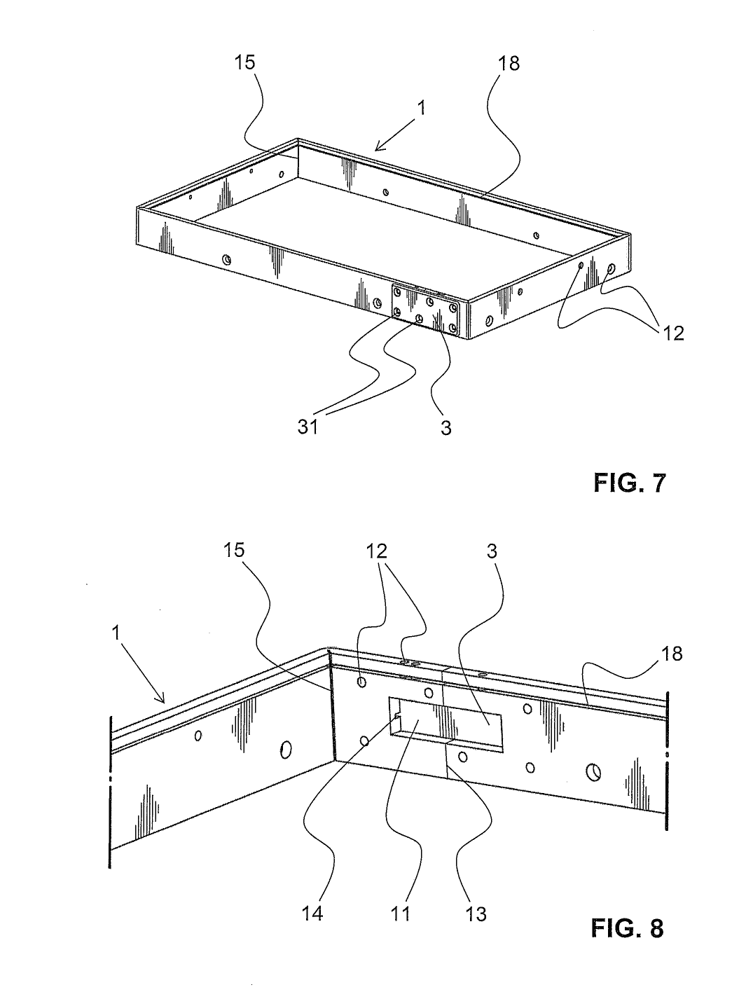

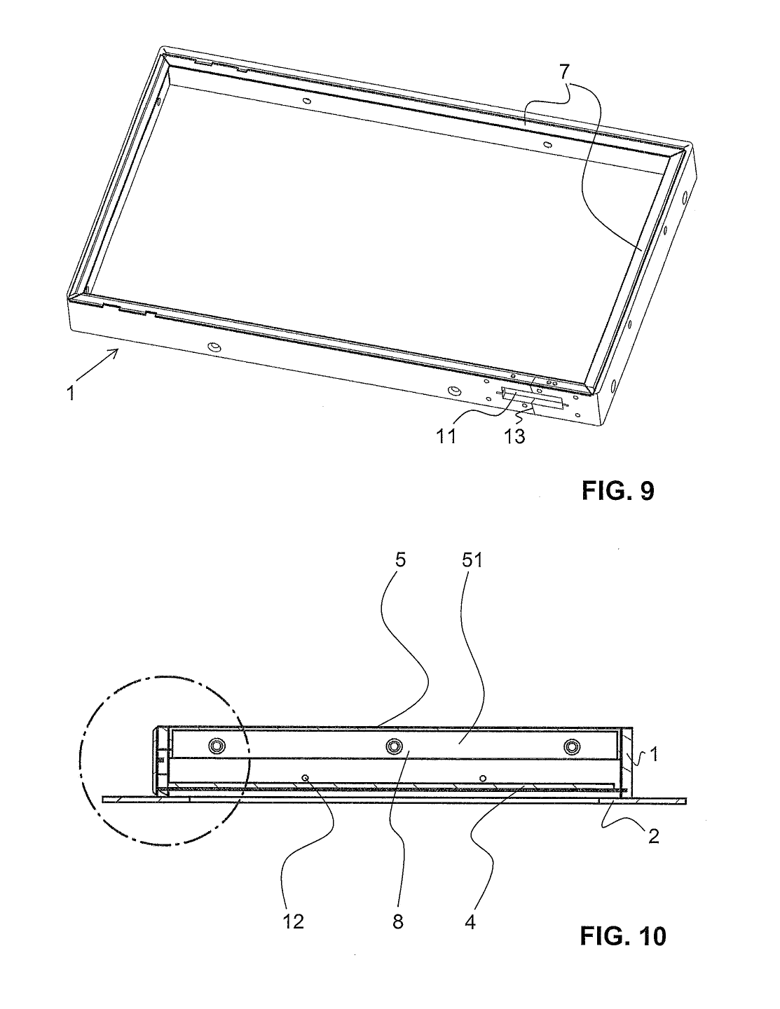

As can be seen in particular in FIGS. 7 and 8 and 11, a peripheral inner channel 18 is formed on the inside of the frame 1. This inner channel 18 is arranged in a front region of the frame 1. The inner channel 18 has preferably already been machined in the flat profile element which has not yet been shaped into a frame 1. The inner channel 18 then extends parallel to the longitudinal direction of the flat profile element and preferably essentially over the entire length of the flat profile element. Alternatively, however, the inner channel 18 can be machined into the inside of the flat profile element only after the latter has been bent into a frame 1. The inner channel 18 serves for the insertion of heat-dissipating strips 7 which can be clearly seen in FIGS. 9 and 11. A heat-dissipating strip 7 is inserted into the inner channel 18, in particular press-fitted into it, in each of the four sides of the rectangular frame 1. The heat-dissipating strips 7 are made from a material which is a good conductor of heat such as in particular a metal sheet. The housing is here designed in such a way that a flat screen held in the housing bears with its forward-facing edge region directly essentially continuously on the respective rearward-facing side of the heat-dissipating strips 7. In this way, heat generated in particular because of the back-lighting can be transmitted to the frame 1 by thermal conduction via the heat-dissipating strips 7.

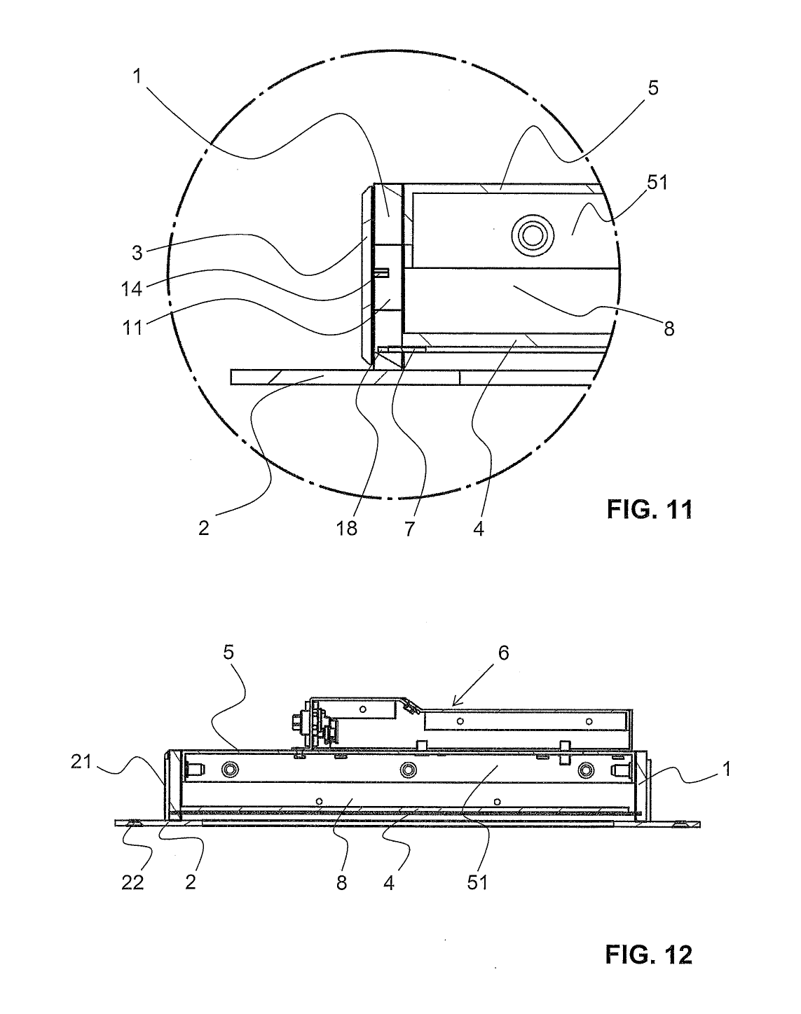

Once the flat screen has been inserted into the housing from the rear, the rear side of the housing is closed by the rear wall 5. The rear wall 5, which can in particular be produced from a simple aluminium sheet, has perpendicularly forward-projecting joining tabs 51 which are arranged essentially continuously around the rear wall 5 (see FIGS. 10 to 12). The joining tabs 51 serve, on the one hand, to fasten the rear wall 5 to the inside of the frame 1 by means of screw joints. On the other hand, however, the joining tabs 51 also serve to produce a thermally conductive joint between the frame 1 and the rear wall 5. Thermal energy which is generated in the flat screen and can be transmitted from the edge strips 7 to the frame 1 can consequently be conducted onwards to the rear wall 5 via the joining tabs 51. Heat-radiating elements such as, for example, rib-like structures which radiate the thermal energy into the surroundings can be attached to the outside surface of the rear wall 5 but also to the outside of the frame 1. In the present embodiment, however, no such heat-radiating elements are provided because the rear wall 5 already has a sufficiently large surface area to radiate the thermal energy generated in the flat screen to the outside.

The rear wall 5 is preferably screwed to the frame 1 in such a way that a flat screen held inside the housing is retained firmly between the heat-dissipating strips 7 and the rear wall 5 and in particular clamped between them. Optimal transmission of heat from the flat screen to the housing can be ensured as a result. Because bolt and nut joints are provided between the joining tabs 51 and the frame 1, and additionally because the corresponding joining holes 12 are designed in such a way that the bolt has a certain amount of play in the joining hole 12 before the respective bolt joint is tightened up, it can be ensured that the rear wall 5 bears closely against the rear side of the flat screen even allowing for manufacturing tolerances.

When producing the housing, the front panel 4 is preferably placed on the forward-facing surfaces of the heat-dissipating strips 7 and is in particular bonded to it. Alternative, less preferred embodiments for the arrangement of the front panel 4 are shown in FIGS. 10 to 12, in which the front panel 4 is bonded to the rearward-facing surfaces of the heat-dissipating strips instead of to the forward-facing surfaces. In this alternative embodiment, the front panel 4 is thus arranged between the heat-dissipating strips 7 and the flat screen. However, the preferred arrangement is one in which the heat-dissipating strips 7 are arranged, in a different fashion to that shown in the Figures, between the front panel 4 and the flat screen.

The invention described here is of course not restricted to the embodiments mentioned and a large number of variations are possible. Thus in particular the production of the frame 1 from a flat profile element with multiple set bending points, on the one hand, and the provision of an inner channel 18 on the frame 1 for the insertion of the heat-dissipating elements 7, on the other hand, represent two independent inventions. It is perfectly conceivable to provide a housing with a frame that is produced from a flat profile element with multiple set bending points but does not have an inner channel for heat-dissipating elements. The heat can then be dissipated in a different manner known to a person skilled in the art. Conversely, equally conceivable is a housing with a frame that has an inner channel for heat-dissipating elements on its inside but is not produced from a flat profile element and instead, for example, from cast aluminium. Where heat-dissipating strips are present, they do not necessarily have to be provided so that they are continuous. A housing with a frame is in particular also conceivable which has, for example, a heat-dissipating strip just along its upper side. In addition, the heat-dissipating elements do not even necessarily have to take the form of strips and can instead take the form of any type of projections that project from the inside of the frame into the housing interior 8 and are suited for bearing against the flat screen. In addition, the frame does not necessarily have to take a form that is completely closed peripherally. When the frame has been fully bent, the two ends of the flat profile element can also be completely spaced apart from each other and it is not absolutely necessary for them to be joined via a joining plate.

The front trim 2, the frame 1, the joining plate 3, the heat-dissipating strips 7, the rear wall 5 and the control circuit module 6 can be joined together in any manner known to a person skilled in the art. In particular bolt, rivet or bonded joints are conceivable for this purpose. Furthermore the set bending points do not necessarily need to be designed as machined grooves and can instead be designed as any type of thinner region of material at the corresponding positions, for example produced by rolling, pressing etc. Set bending points based on perforations at the corresponding positions of the flat profile element are also possible.

In addition, in an alternative embodiment, other heat-dissipating elements can be attached to the inner surface of the rear wall 5 which are provided for bearing against the rear wall of the flat screen. These heat-dissipating elements can in particular be designed in such a way that, by virtue of their shape, they can be compressed elastically at least slightly in a direction perpendicular to the inner surface of the rear wall. The heat-dissipating elements are then therefore tensioned between the two surfaces of the rear wall and the flat screen in a similar manner to a spring. Such a shape for these additional heat-dissipating elements can be achieved, for example, by them having an overall Z- or S-shape. The compressibility ensures that these heat-dissipating elements can bear against the flat screen held in the housing at all times, taking manufacturing tolerances into account, and as a result divert the heat generated to the rear wall and hence to the outside.

A large number of other variations is conceivable.

1. A housing for holding a flat screen comprising a frame that defines a housing interior for holding the flat screen, wherein the frame is produced from a flat profile element that has multiple set bending points that serve to establish the corner regions of the frame.

2. The housing according to claim 1, wherein the set bending points are each defined by a thinner region of material at the corresponding position.

3. The housing according to claim 2, wherein the thinner regions of material are each formed by a groove that is delimited by two flat surfaces and a curved surface arranged between the two flat surfaces.

4. The housing according to claim 3, wherein the two flat surfaces enclose an angle of more than 80° and less than 100°.

5. The housing according to claim 1, wherein the frame has an inner channel on its side facing the housing interior, and wherein the housing has at least one heat-dissipating element which is inserted into the inner channel of the frame, and which serves to transmit heat generated in the housing interior to the frame.

6. The housing according to claim 1, wherein the frame has a joining point at which the two ends of the flat profile element are joined together.

7. The housing according to claim 1, wherein the frame has a recess which serves to hold an electronic component.

8. The housing according to claim 1, wherein the housing has a rear wall to which at least one joining tab is attached which serves to join the rear wall to the frame.

9. A housing for holding a flat screen, comprising a frame which defines a housing interior for holding the flat screen, and at least one heat-dissipating element which is attached to the inside of the frame and which serves to transmit heat generated in the housing interior to the frame, wherein the frame is produced from a flat profile element that has multiple set bending points that serve to establish the corner regions of the frame, and wherein the frame has an inner channel, into which the heat-dissipating element is inserted, on its side facing the housing interior.

10. The housing according to claim 9, wherein the heat-dissipating element is a strip.

11. The housing according to claim 9, wherein the housing has a front panel which is bonded to the heat-dissipating element.

12. A method for producing a housing for holding a flat screen, comprising the steps of:
(i) providing a frame which defines a housing interior for holding the flat screen, wherein multiple set bending points are provided for a flat profile element, and
(ii) bending the flat profile element in the regions of these set bending points in such a way that in each case a corner region of the frame is formed.

13. The method according to claim 12, further comprising the step of providing an inner channel on the flat profile element, which is arranged in such a way that it extends, on the one hand, in the longitudinal direction of the flat profile element, and in that, on the other hand, it is situated on the inside of the frame after the flat profile element has been bent.

14. The method according to claim 12, further comprising the step of producing the set bending points by using a machining process.

15. (canceled)
